(19) United States
(12) Patent Application Publication
(10) Pub. No.: US 2025/0210470 A1
(43) Pub. Date: Jun. 26, 2025

(54) POLYMERIC DIE PAD FOR DIE ISOLATION IN CHIP ON LEAD PACKAGE

(71) Applicant: Texas Instruments Incorporated, Dallas, TX (US)

(72) Inventors: Rongwei Zhang, Plano, TX (US); Hank Sung, Sachse, TX (US); Yuntao Xu, Chengdu (CN)

(21) Appl. No.: 18/395,593

(22) Filed: Dec. 24, 2023

(51) Int. Cl. H01L 23/495; H01L 21/48; H01L 23/00

(52) U.S. Cl. CPC H01L 23/49503; H01L 21/4842; H01L 23/49541; H01L 23/49568; H01L 24/48; H01L 2224/48465; H01L 2924/351

(57) ABSTRACT

A semiconductor package includes a polymeric die pad attached to a plurality of the leads of a lead frame portion. The polymeric die pad is electrically non-conductive. The leads are electrically conductive, and extend to an exterior of the semiconductor package. The polymeric die pad may be punched from a polymeric tape and pressed onto the leads. The polymeric die pad may be removed from a precut polymeric tape and placed on the leads by a pick-and-place operation. A semiconductor die is attached to the polymeric die pad, opposite from the leads. The semiconductor die is electrically isolated from the leads by the polymeric die pad. The polymeric die pad extends laterally past the semiconductor die on all sides. The semiconductor package may be formed by attaching the semiconductor die to the polymeric die pad after the polymeric die pad is attached to the leads.

### TECHNICAL FIELD

This disclosure relates to the field of semiconductor packages. More particularly, but not exclusively, this disclosure relates to semiconductor packages with lead frames.

### BACKGROUND

Semiconductor devices, such as integrated circuits and discrete components, are essential components of modern electronic systems. These devices are typically housed within semiconductor packages to protect them from environmental factors and facilitate integration into various electronic applications. The semiconductor packages commonly include leads that are electrically connected to the integrated circuits and discrete components. Reducing costs and reducing footprints of the semiconductor packages are ongoing efforts.

### SUMMARY

A semiconductor package includes a lead frame portion that includes leads, and includes a polymeric die pad attached to a plurality of the leads. The leads are electrically conductive, and extend to an exterior of the semiconductor package. A semiconductor die is attached to the polymeric die pad. The polymeric die pad is electrically non-conductive. The polymeric die pad extends laterally past the semiconductor die on all sides. The semiconductor package may be formed by attaching the polymeric die pad to the leads and subsequently attaching the semiconductor die to the polymeric die pad.

### BRIEF DESCRIPTION OF THE FIGURES

FIG. 1A through FIG. 1H depict an example semiconductor package including a polymeric die pad, shown in stages of an example method of formation.

FIG. 2A through FIG. 2F depict another example semiconductor package including a polymeric die pad, shown in stages of another example method of formation.

FIG. 3A and FIG. 3B are a top view and a cross section of a further example semiconductor package including a polymeric die pad.

FIG. 4A and FIG. 4B are a top view and a cross section of another example semiconductor package including polymeric die pads.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

A semiconductor package includes a portion of a lead frame, herein the lead frame portion. The lead frame portion includes leads that are electrically conductive and extend from an interior of the semiconductor package to an exterior of the semiconductor package. The semiconductor package includes a polymeric die pad attached to a plurality of the leads. The polymeric die pad is electrically non-conductive. For the purposes of this disclosure, the term “polymeric” refers to a solid material that includes more than 90 weight percent of organic polymer, such as polyimide, polyester, silicone, epoxy, polyurethane, or acrylic. In some versions of this disclosure, the polymeric die pad may be attached to the leads though a die pad adhesive that is adhered to the polymeric die pad. The die pad adhesive is also electrically non-conductive. The semiconductor package includes a semiconductor die attached to the polymeric die pad. In some versions of this disclosure, the semiconductor die may be attached to the polymeric die pad through a die attach paste which may be dispensed onto the polymeric die pad. In some versions of this disclosure, the semiconductor die may be attached to the polymeric die pad through a die attach film. The polymeric die pad extends laterally past the semiconductor die on all sides, which may advantageously reduce a risk of a current leakage path from the semiconductor die to one or more of the leads due to conductive debris, such as semiconductor particles, resulting from singulation of the semiconductor die. For the purposes of this disclosure, the terms “laterally” and “lateral” refer to directions parallel to the surface of the polymeric die pad to which the semiconductor die is attached.

The semiconductor die is electrically connected to one or more of the leads. In some versions of this disclosure, the semiconductor package may include two separate semiconductor die attached to the polymeric die pad. In some versions of this disclosure, the semiconductor package may include two polymeric die pads attached to leads, with separate semiconductor die attached to each of the polymeric die pads. The polymeric die pad may electrically isolate the semiconductor die from one or more of the leads to which the polymeric die pad is attached. The polymeric die pad may enable a lower cost semiconductor package compared to other configurations that isolate a semiconductor die from one or more leads. The polymeric die pad may enable a reduced package area for the semiconductor package, compared to semiconductor packages having electrically conducting die pads that are parts of lead frames, by having the semiconductor die partially overlap the leads while being electrically isolated from the leads.

A semiconductor package may be formed by attaching a polymeric die pad to leads of a lead frame. The polymeric die pad is electrically non-conductive. In some versions of this example, the polymeric die pad may be punched out of a polymeric tape. In some versions of this example, the polymeric die pad may be cut from a polymeric tape on a backing sheet. The polymeric die pad may have a die pad adhesive attached to the polymeric die pad, in which case attaching the polymeric die pad to the leads includes curing the die pad adhesive. A semiconductor die is attached to the polymeric die pad. The polymeric die pad extends laterally past the semiconductor die on all sides. Electrical connections between the semiconductor die and one or more of the leads are formed. The polymeric die pad may advantageously be formed at lower cost than ceramic or rigid fiber reinforced polymer (FRP) die pads. Ceramic die pads must be dispensed as green slurry tapes and fired, incurring significantly higher cost then the polymeric die pad. Similarly, rigid FRP die pads are more expensive to produce and more expensive to cut to size, due to the fiber reinforcing material. The die pad adhesive adhered to the polymeric die pad advantageously provides a lower cost attachment process compared to dispensing adhesive paste, needed for ceramic and FRP die pads.

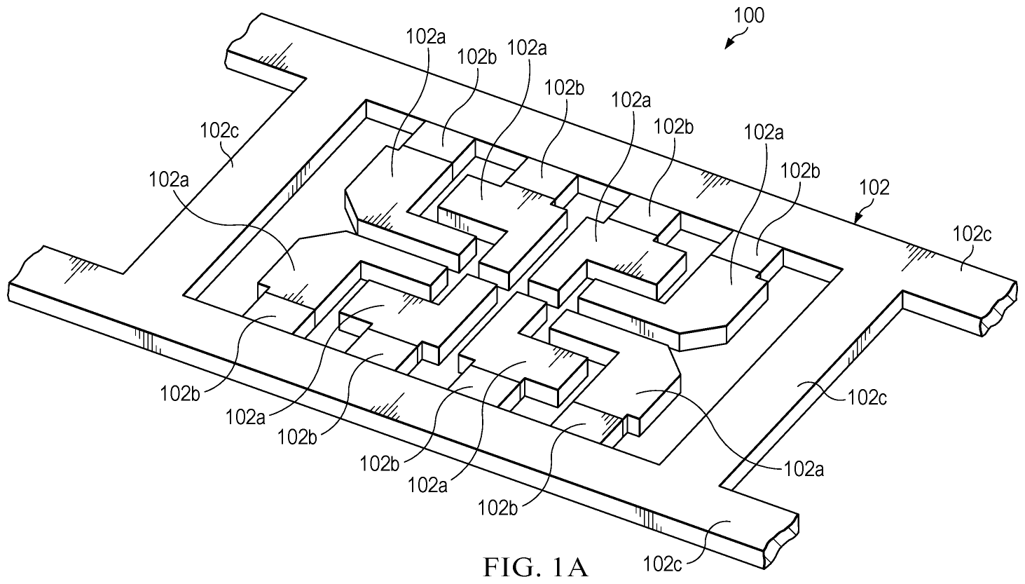

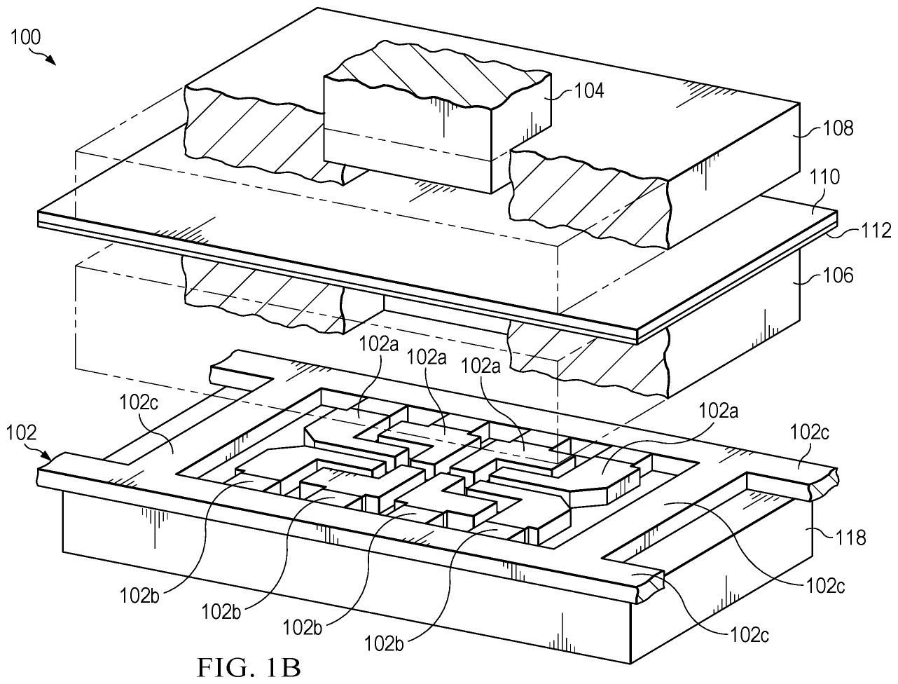

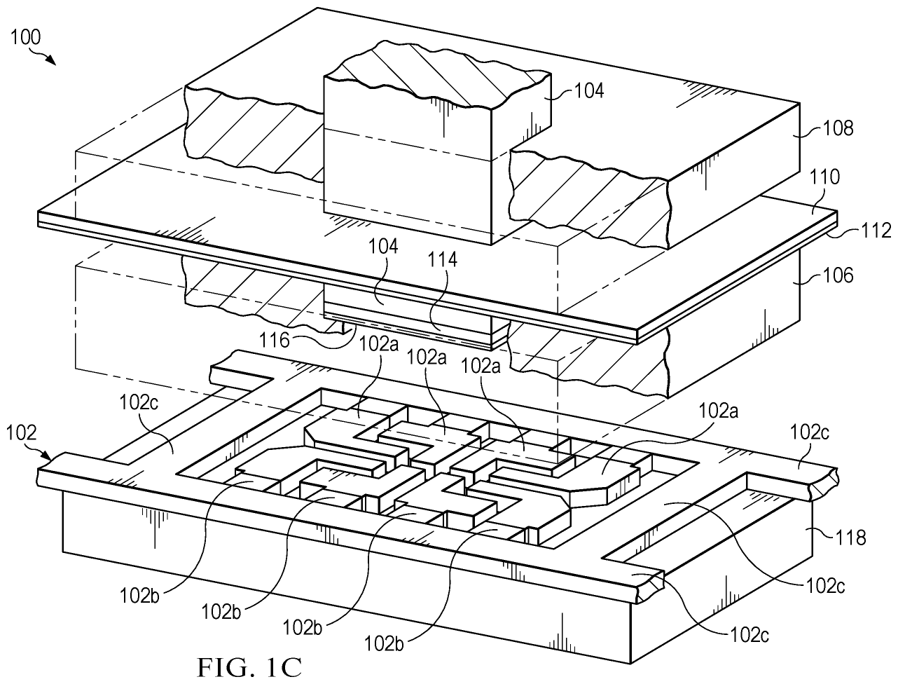

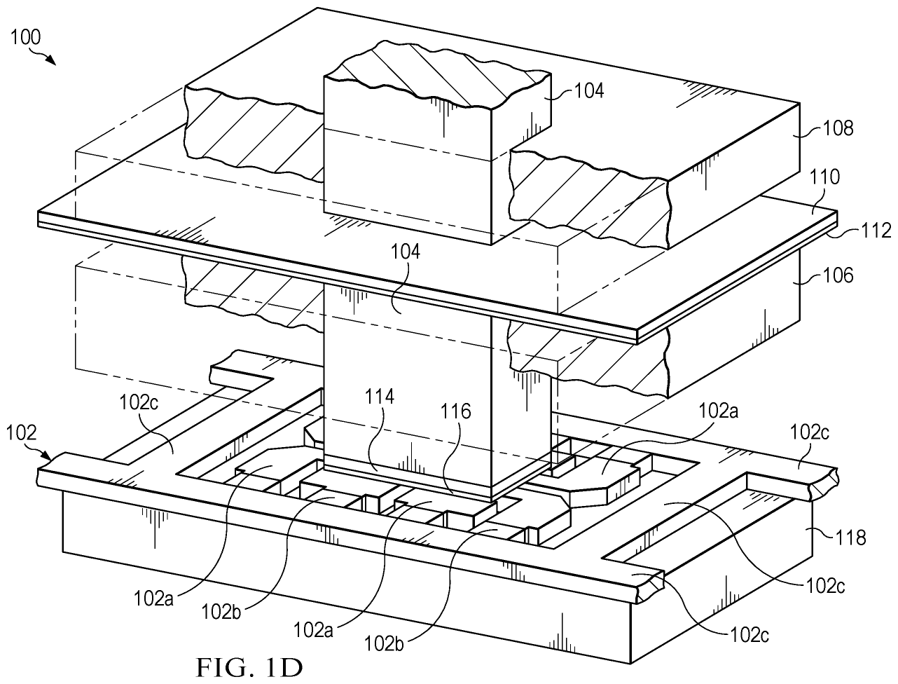

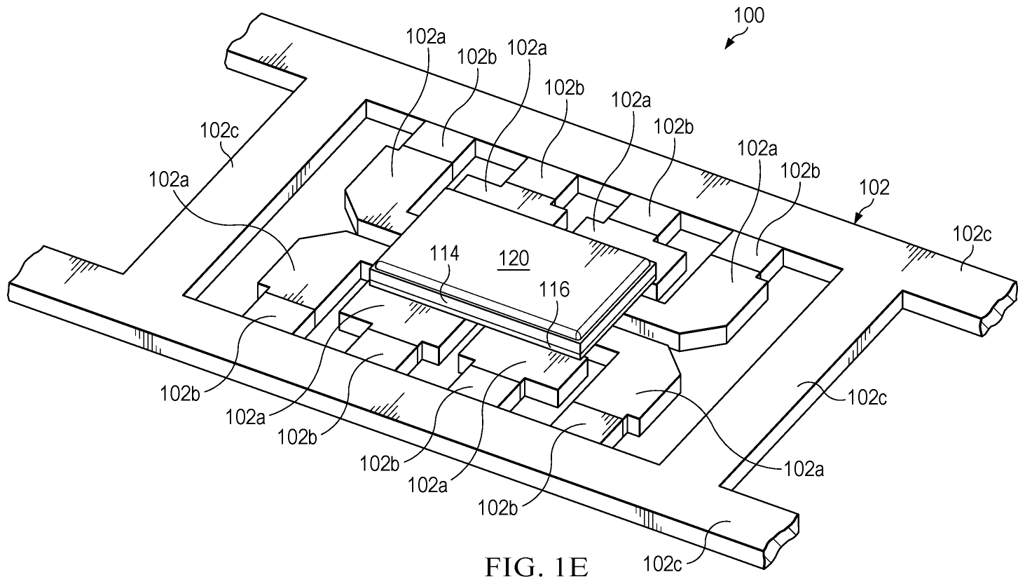

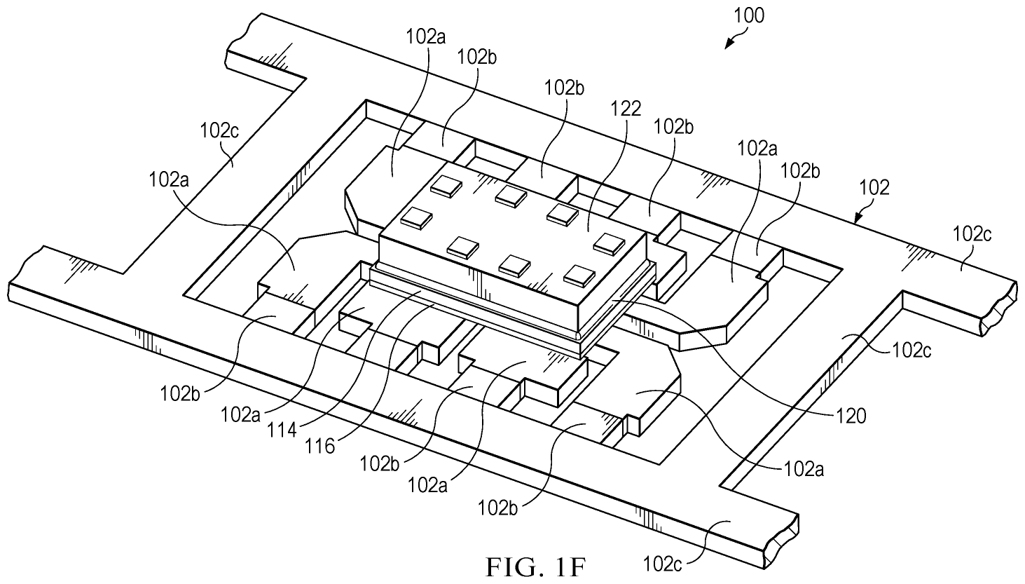

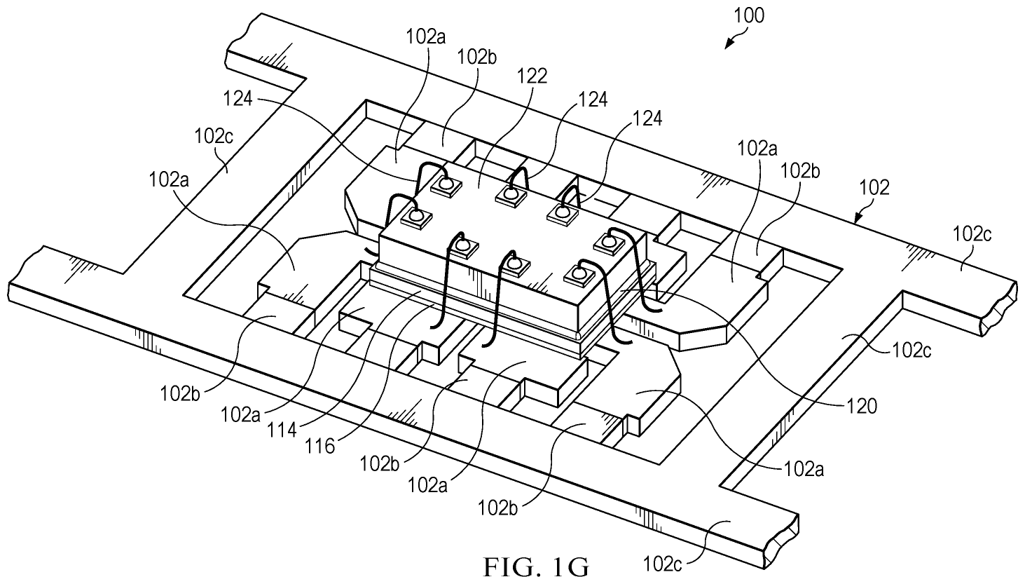

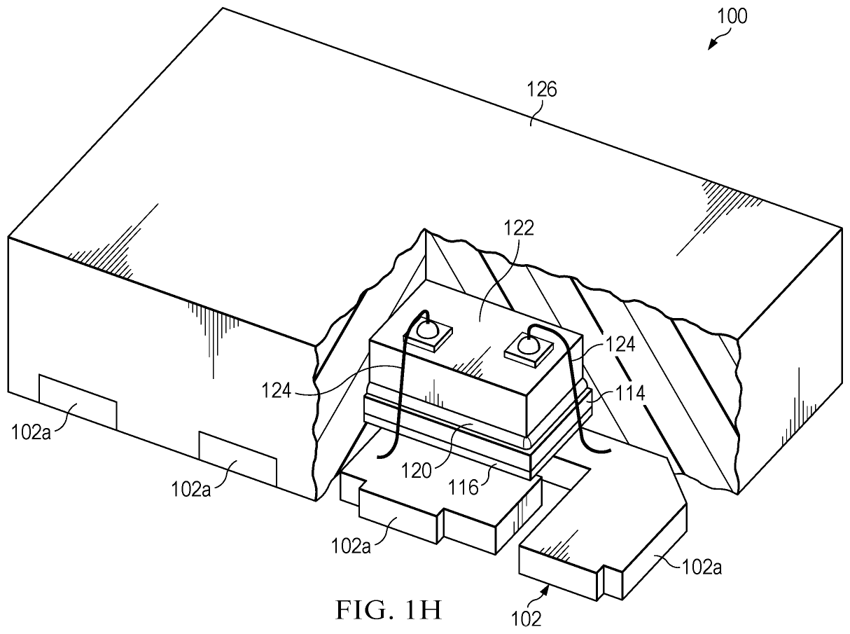

FIG. 1A through FIG. 1H depict an example semiconductor package including a polymeric die pad, shown in stages of an example method of formation. Referring to FIG. 1A, the semiconductor package 100 is formed on a lead frame 102. The lead frame 102 includes leads 102a that extend from an interior of the semiconductor package 100 to an exterior of the semiconductor package 100. In this example, the lead frame 102 may include tie bars 102b which connect the leads 102a to rails 102c of the lead frame 102. The lead frame 102 may include copper, stainless steel, or alloy 42, by way of example. Alloy 42 is an iron-nickel alloy containing 42% nickel. The lead frame 102 may be plated with nickel and gold, or with silver. Other materials and plated layers for the lead frame 102 are within the scope of this example.

A portion, or all, of the leads 102a may have textured surfaces to improve adhesion to the polymeric die pad. The textured surfaces may include raised bumps, pits, or grooves, by way of example. The raised bumps may be formed by an electroless plating process. The pits may be formed by etching before electroplating the nickel, gold, or silver, or by stamping, before or after electroplating. The grooves may be formed by stamping, before or after electroplating.

The lead frame 102 may include additional leads, not specifically shown, for additional semiconductor packages, along a length of the lead frame 102. The additional semiconductor packages may be disposed in a linear array along the lead frame 102, or may be disposed in a rectangular array across the lead frame 102.

Referring to FIG. 1B, the lead frame 102 is positioned below a punch 104. At this step, depicted in FIG. 1B, the punch 104 is located above a die 106. The die 106 has an opening to allow the punch 104 to travel through the opening. The punch may be surrounded by a stripper 108, located above the die 106.

A polymeric tape 110 is positioned under the punch 104, between the die 106 and the stripper 108. The polymeric tape 110 is electrically non-conductive, and includes more than 90 weight percent of organic polymer. The polymeric tape 110 may be, by way of example, 10 microns to 100 microns thick. The thickness of the polymeric tape 110 may be selected to provide desired levels of thermal conductivity, mechanical rigidity, and dielectric isolation in the semiconductor package 100. Thermal conductivity affects removal of heat from a subsequently assembled semiconductor die. Mechanical rigidity affects uniformity of a bond line of a subsequently formed die adhesive, and is affected by spacing between the leads 102a. Dielectric isolation affects electrical isolation between the semiconductor die and the leads 102a.

A die pad adhesive layer 112 may be adhered to the polymeric tape 110. The die pad adhesive layer 112 may include, by way of example, silicone adhesive, b-staged epoxy, or nitrile butadiene rubber (NBR). The die pad adhesive layer 112 may be 5 microns to 25 microns thick, by way of example. The die pad adhesive layer 112 is electrically non-conductive.

Referring to FIG. 1C, the punch 104 is pushed through the polymeric tape 110, removing a polymeric die pad 114 from the polymeric tape 110, and transporting the polymeric die pad 114 toward the lead frame 102. A portion of the die pad adhesive layer 112 that is removed by the punch 104 may be adhered to the polymeric die pad 114 to provide a die pad adhesive 116, as depicted in FIG. 1C. The polymeric tape 110 and the die pad adhesive layer 112 are restrained by the die 106 as the punch 104 is pushed through the polymeric tape 110. A die pad heater 118 may be positioned under the lead frame 102 to provide heat to the lead frame 102 to subsequently cure the die pad adhesive 116.

Referring to FIG. 1D, the polymeric die pad 114 and the die pad adhesive 116 are pressed on the lead frame 102 by the punch 104. The die pad heater 118 heats the lead frame 102, which cures the die pad adhesive 116, attaching the polymeric die pad 114 to the leads 102a. Adhesion of the polymeric die pad 114 to the leads 102a may advantageously be improved by the textured surfaces on the leads 102a. The die pad heater 118 may provide a cure cycle of 180° C. for a few seconds, by way of example. Other cure cycles are within the scope of this example.

After the die pad adhesive 116 is cured, the punch 104 is retracted. The stripper 108 restrains the polymeric tape 110 as the punch 104 is retracted. The polymeric tape 110 is subsequently moved to expose another portion of the polymeric tape 110 between the die 106 and the stripper 108 for another semiconductor package, not specifically shown.

Referring to FIG. 1E, die attach paste 120 is dispensed on the polymeric die pad 114, opposite from the leads 102a. The die attach paste 120 may include filler particles, such as aluminum oxide particles, silicon dioxide particles, silver flakes, or nickel-plated copper particles. The filler particles may improve adhesion to the polymeric die pad 114.

Referring to FIG. 1F, the semiconductor die 122 is placed on the die attach paste 120. The semiconductor die 122 may be held in place by stickiness of the die attach paste 120, enabling the lead frame 102 to be transported from a paste dispensing station to a paste curing station. The die attach paste 120 is subsequently cured, adhering the semiconductor die 122 to the polymeric die pad 114. Use of the die attach paste 120 may enable separation of the paste dispensing operation from the paste curing operation, providing higher throughput compared to a die attach process that requires the die attach adhesive to be cured in place. The semiconductor die 122 of this example partially overlaps the leads 102a. The die attach paste 120 may extend past the semiconductor die 122 to provide a more complete bond line between the semiconductor die 122 and the polymeric die pad 114. The polymeric die pad 114 extends laterally past the semiconductor die 122 on all sides of the semiconductor die 122. The semiconductor die 122 is electrically isolated from the leads 102a by the polymeric die pad 114. In this example, the polymeric die pad 114 extends laterally past the die attach paste 120 on all sides of the die attach paste 120, which may advantageously reduce a risk of a current leakage path from the semiconductor die 122 to one or more of the leads 102a due to conductive debris in the die attach paste 120. Thus, in this example, the polymeric die pad 114 may extend laterally past the semiconductor die 122 by 100 microns to 200 microns on all sides of the semiconductor die 122. The lateral extension of the polymeric die pad 114 past the semiconductor die 122 may be adjusted to account for placement tolerance and dispensing tolerance of the dispensing process for the die attach paste 120.

Referring to FIG. 1G, electrical connections 124 are formed between the semiconductor die 122 and the leads 102a. The electrical connections 124 may be implemented as wire bonds, as depicted in FIG. 1G, as ribbon bonds, as clips, as additively formed connections, or other types of electrical connections. Having the semiconductor die 122 partially overlapping the leads 102a may enable the electrical connections 124 to be terminated on the leads 102a close to the polymeric die pad 114, advantageously enabling a reduced area for the semiconductor package 100 compared to package configurations having lead frame die pads.

Referring to FIG. 1H, a packaging material 126 is formed on the semiconductor die 122 and the leads 102a, surrounding the polymeric die pad 114, and covering the electrical connections 124. The packaging material 126 is electrically non-conductive. The leads 102a are separated from the remainder of the lead frame 102 by a singulation process. The leads 102a extend to an exterior of the semiconductor package 100. In this example, the semiconductor package 100 is implemented as a quad flat pack, no leads (QFN) package. The packaging material 126 may include epoxy, and may include filler particles, such as aluminum oxide particles or silicon dioxide particles, to reduce a thermal expansion coefficient of the packaging material 126.

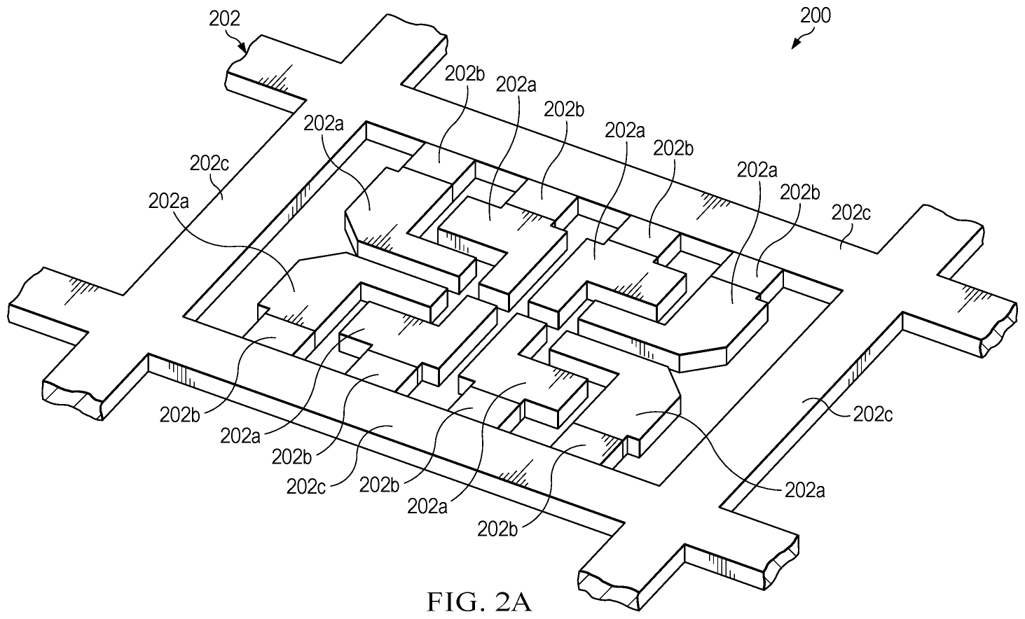

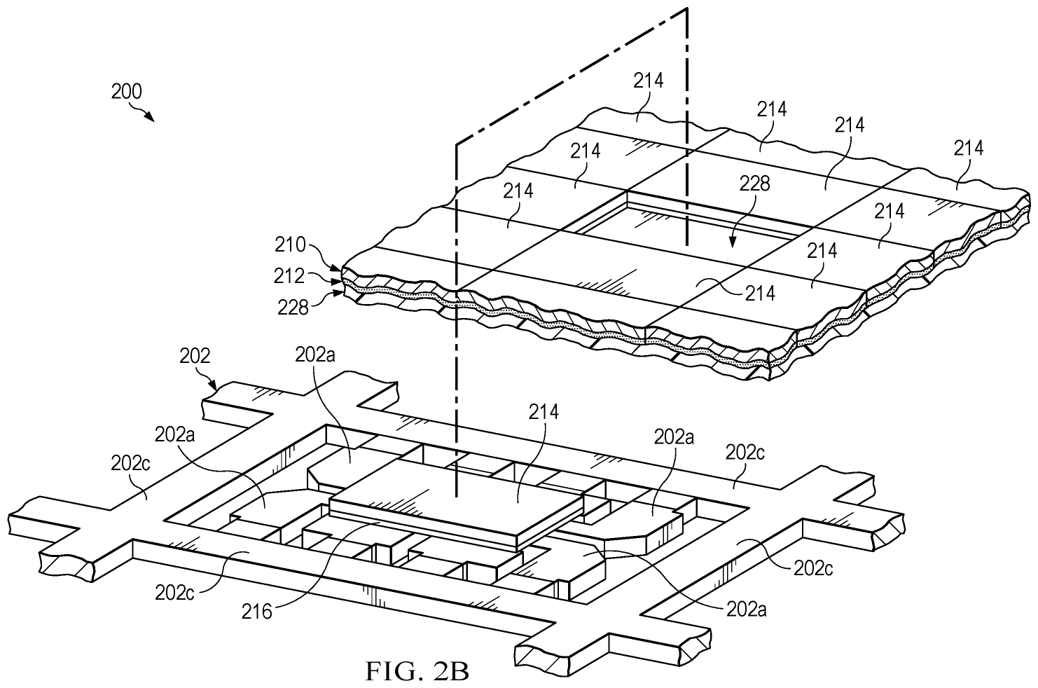

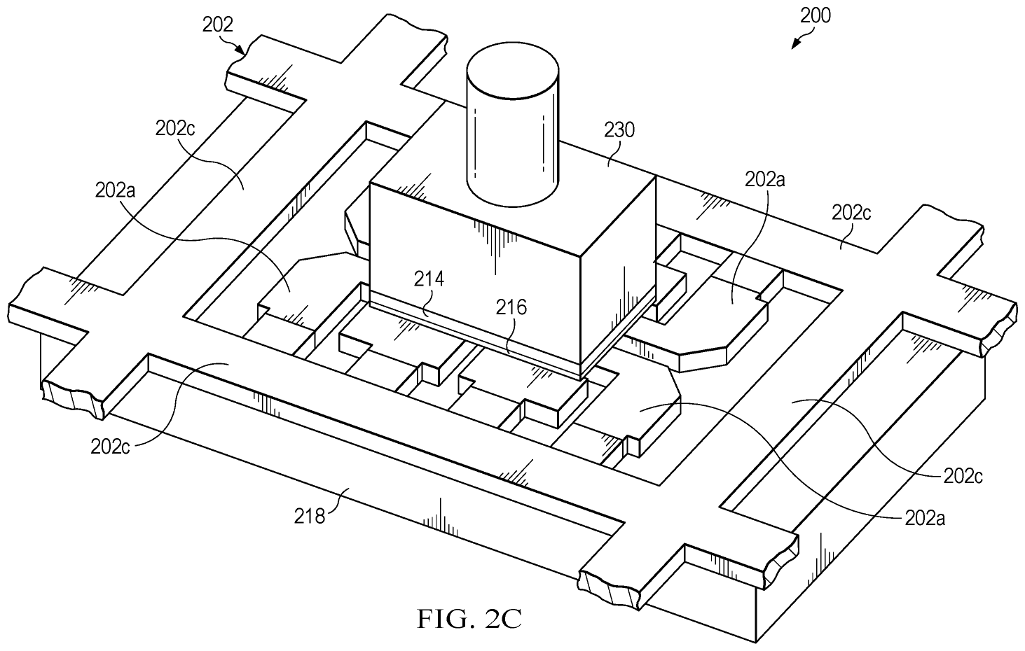

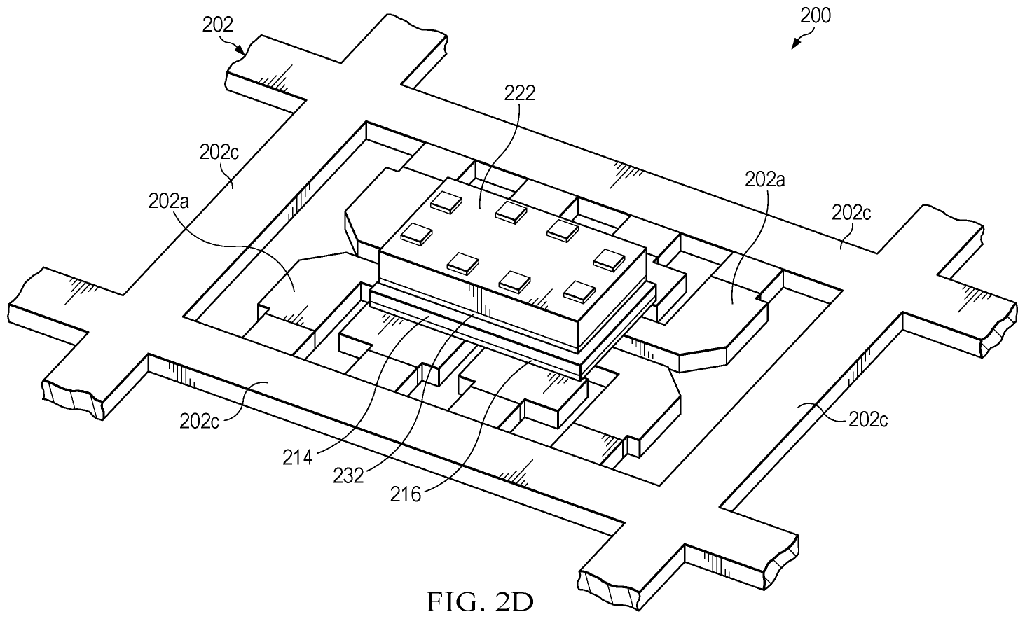

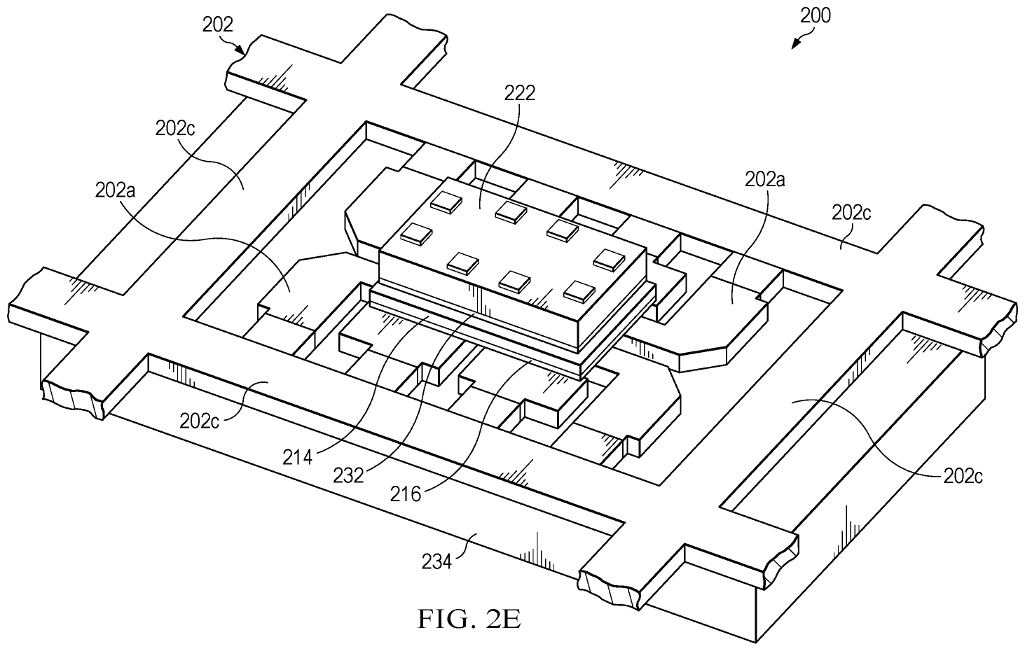

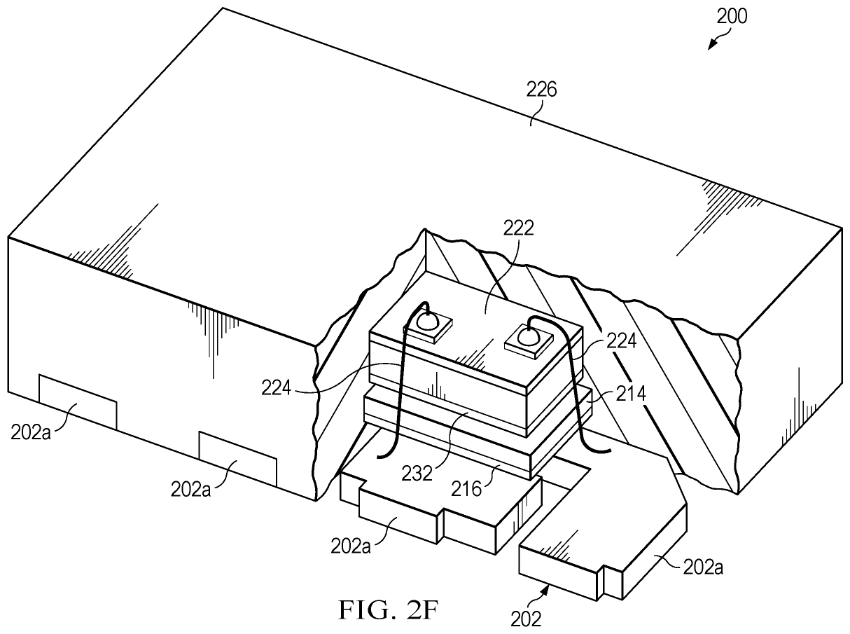

FIG. 2A through FIG. 2F depict another example semiconductor package including a polymeric die pad, shown in stages of another example method of formation. Referring to FIG. 2A, the semiconductor package 200 is formed on a lead frame 202. The lead frame 202 includes leads 202a that extend from an interior of the semiconductor package 200 to an exterior of the semiconductor package 200. In this example, the lead frame 202 may include tie bars 202b which connect the leads 202a to rails 202c of the lead frame 202. The lead frame 202 may include additional leads, not specifically shown, for additional semiconductor packages, disposed in a rectangular array across the lead frame 202.

Referring to FIG. 2B, a polymeric tape 210 is electrically non-conductive, and includes a polymer material. A die pad adhesive layer 212, which is also electrically non-conductive, may be adhered to the polymeric tape 210. A backing layer 228 holds the die pad adhesive layer 212 and the polymeric tape 210. The polymeric tape 210 and the die pad adhesive layer 212 are cut into polymeric die pads 214 and die pad adhesives 216. The backing layer 228 is not cut through, in this example, in order to hold the polymeric die pads 214 and die pad adhesives 216 in place. The polymeric tape 210 and the die pad adhesive layer 212 may be cut by a laser cutter or a stylus cutter, by way of example. The polymeric die pads 214 and die pad adhesives 216 may be arranged in a rectangular array, as depicted in FIG. 2B.

An instance of the polymeric die pads 214 and die pad adhesives 216 is transferred from the backing layer 228 to the lead frame 202. The polymeric die pad 214 and die pad adhesive 216 may be transferred by a pick-and-place operation, by way of example. The die pad adhesive 216 contacts the leads 202a. Additional instances of the polymeric die pads 214 and die pad adhesives 216 may be transferred to additional leads across the lead frame 202 for additional semiconductor packages.

Referring to FIG. 2C, a die pad heater 218 is disposed below the lead frame 202, and a press plate 230 is disposed on the polymeric die pad 214. The press plate 230 presses the die pad adhesive 216 onto the leads 202a while the die pad heater 218 heats the leads 202a. Heating the leads 202a in turn heats the die pad adhesive 216, curing the die pad adhesive 216. The polymeric die pad 214 is thus adhered to the leads 202a through the die pad adhesive 216.

Referring to FIG. 2D, a semiconductor die 222 has a die attach film 232 adhered to a bottom surface of the semiconductor die 222. The die attach film 232 in this example is coterminous with the semiconductor die 222, as depicted in FIG. 2D. The die attach film 232 may be singulated with the semiconductor die 222. The semiconductor die 222 and the die attach film 232 are disposed on the polymeric die pad 214, with the die attach film 232 contacting the polymeric die pad 214. The polymeric die pad 214 extends laterally past the semiconductor die 222 on all sides of the semiconductor die 222. In this example, because the die attach film 232 is coterminous with the semiconductor die 222, the polymeric die pad 214 may extend laterally past the semiconductor die 222 by 40 microns to 80 microns on all sides of the semiconductor die 222 and advantageously reduce a risk of a current leakage path from the semiconductor die 222 to one or more of the leads 202a due to conductive debris in the die attach film 232 or along the sides of the semiconductor die 222. Having the polymeric die pad 214 extend laterally past the semiconductor die 222 by 40 microns to 80 microns may enable a reduced package area for the semiconductor package, compared to semiconductor packages with larger lateral extensions of corresponding die pads.

Referring to FIG. 2E, the lead frame 202 is positioned over a die attach heater 234. The die attach heater 234 heats the die attach film 232 through the leads 202a, the die pad adhesive 216, and the polymeric die pad 214, curing the die attach film 232, and thus adhering the semiconductor die 222 to the polymeric die pad 214. The die attach heater 234 may provide a cure cycle of 100° C. for 5 seconds, or 180° C. for 500 milliseconds, by way of example. Other cure cycles are within the scope of this example. The semiconductor die 222 may be pressed onto the polymeric die pad 214, through the die attach film 232, during the cure cycle to improve uniformity of adhesion.

Referring to FIG. 2F, electrical connections 224 are formed between the semiconductor die 222 and the leads 202a. Having the semiconductor die 222 partially overlapping the leads 202a may accrue the advantage of reduced area for the semiconductor package 200. A packaging material 226, which is electrically non-conductive, is formed on the semiconductor die 222 and the leads 202a, surrounding the polymeric die pad 214, and covering the electrical connections 224. The leads 202a are separated from the remainder of the lead frame 202 by a singulation process, such as a saw process. The leads 202a extend to an exterior of the semiconductor package 200 to form a QFN package. Other package types are within the scope of this example.

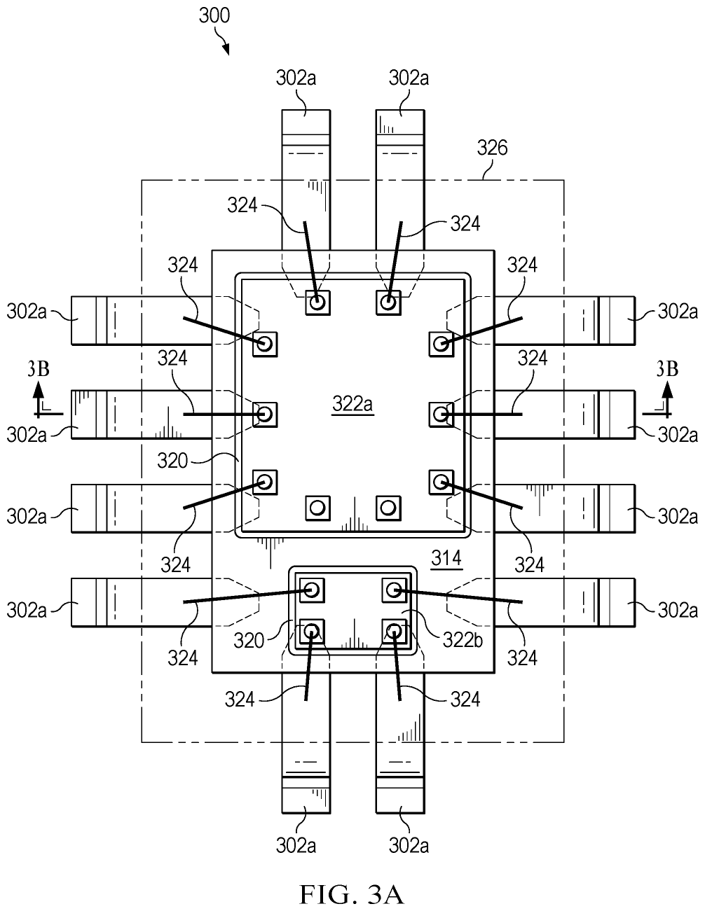

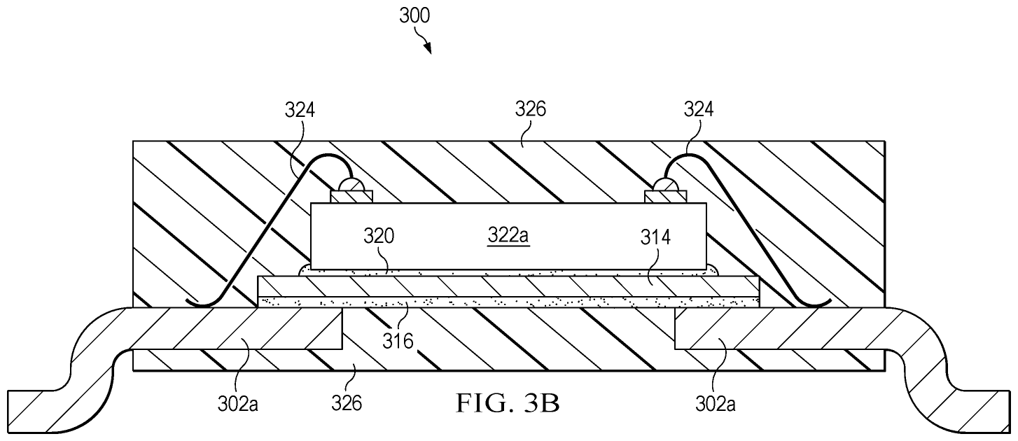

FIG. 3A and FIG. 3B are a top view and a cross section of a further example semiconductor package including a polymeric die pad. The semiconductor package 300 includes leads 302a that extend from an interior of the semiconductor package 300 to an exterior of the semiconductor package 300. The leads 302a are electrically conductive, and may have any of the compositions disclosed in reference to the lead frame 102 of FIG. 1A. A polymeric die pad 314 of the semiconductor package 300 is attached to the leads 302a through a die pad adhesive 316. The polymeric die pad 314 and the die pad adhesive 316 may have any of the compositions disclosed in reference to the polymeric tape 110 and the die pad adhesive layer 112 of FIG. 1B. The polymeric die pad 314 and the die pad adhesive 316 are electrically non-conductive.

A first semiconductor die 322a of the semiconductor package 300 is attached to the polymeric die pad 314 through a die attach paste 320, opposite from the leads 302a. The first semiconductor die 322a partially overlaps a first plurality of the leads 302a. A second semiconductor die 322b of the semiconductor package 300 is attached to the polymeric die pad 314 through the die attach paste 320, opposite from the leads 302a, and adjacent to the first semiconductor die 322a. The second semiconductor die 322b partially overlaps a second plurality of the leads 302a. The first semiconductor die 322a is electrically isolated from the second semiconductor die 322b by the electrical non-conductive property of the polymeric die pad 314. Having the first semiconductor die 322a and the second semiconductor die 322b adjacent to each other on the polymeric die pad 314, while being electrically isolated from each other, may advantageously enable a reduced area for the semiconductor package 300 compared to a semiconductor package with lead frame die pads for each die.

The semiconductor package 300 includes electrical connections 324 between the first semiconductor die 322a and one or more of the leads 302a, and between the second semiconductor die 322b and another or more of the leads 302a. The electrical connections 324 may be implemented as any of the connections disclosed in reference to the electrical connections 124 of FIG. 1G.

A packaging material 326 is formed on the first semiconductor die 322a and the second semiconductor die 322b, and the leads 302a, surrounding the polymeric die pad 314, and covering the electrical connections 324. The packaging material 326 is electrically non-conductive, and may have any of the compositions disclosed in reference to the packaging material 126 of FIG. 1H. In this example, the leads 302a may extend from the packaging material 326 in a “gull wing” configuration, so that the semiconductor package 300 is implemented as a small outline package, such as a small outline transistor (SOT) package, a small outline integrated circuit (SOIC) package, or a quad flat pack (QFP) package. Other package type for the semiconductor package 300 are within the scope of this example.

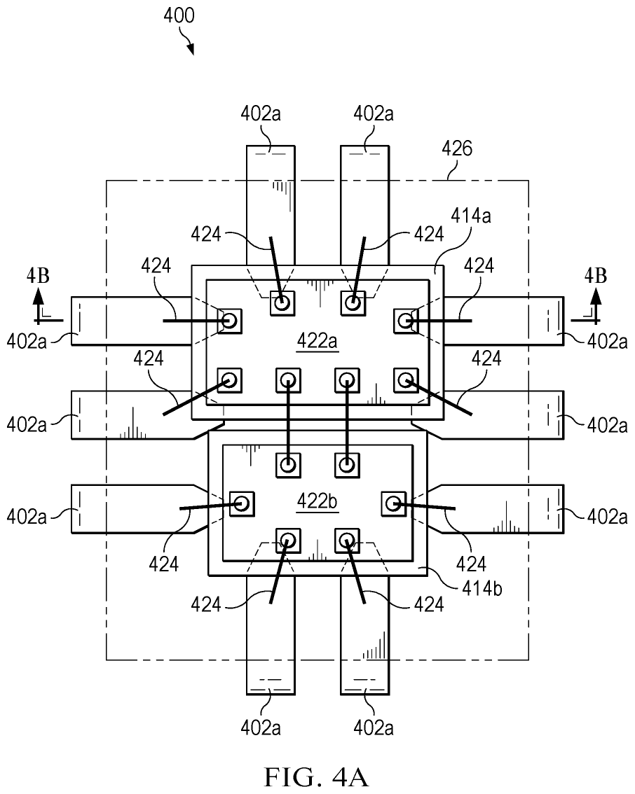

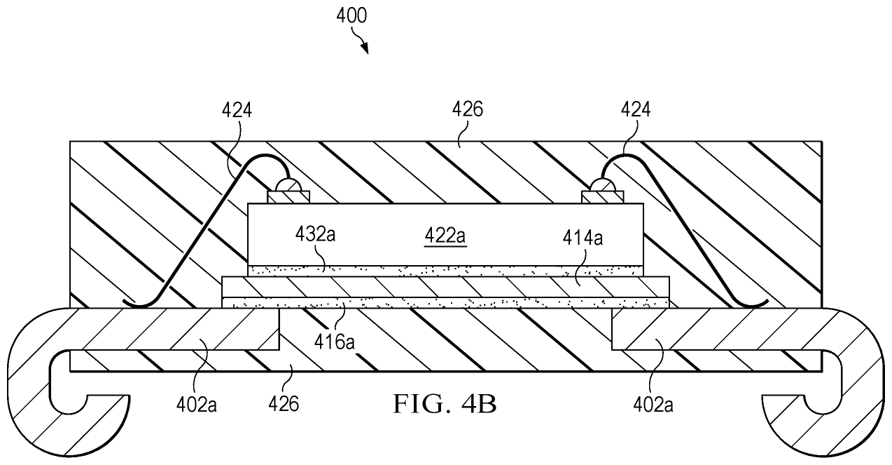

FIG. 4A and FIG. 4B are a top view and a cross section of another example semiconductor package including polymeric die pads. The semiconductor package 400 includes leads 402a that are electrically conductive, and that extend from an interior of the semiconductor package 400 to an exterior of the semiconductor package 400. In this example, a first polymeric die pad 414a of the semiconductor package 400 is attached to a first plurality of the leads 402a through a first die pad adhesive 416a. In this example, the first die pad adhesive 416a may be coterminous with the first polymeric die pad 414a, as indicated in FIG. 4B. A second polymeric die pad 414b of the semiconductor package 400 is attached to a second plurality of the leads 402a through a second die pad adhesive, not specifically shown, adjacent to the first semiconductor die 422a.

A first semiconductor die 422a of the semiconductor package 400 is attached to the first polymeric die pad 414a through a first die attach film 432a, opposite from the leads 402a. The first semiconductor die 422a partially overlaps a first plurality of the leads 402a. A second semiconductor die 422b of the semiconductor package 400 is attached to the second polymeric die pad 414b through a second die attach film, not specifically shown, opposite from the leads 402a. The second semiconductor die 422b partially overlaps a second plurality of the leads 402a. The first semiconductor die 422a is electrically isolated from the second semiconductor die 422b by the electrical non-conductive properties of the polymeric die pads 414a and 414b. Having separate polymeric die pads 414a and 414b for the first and second semiconductor die 422a and 422b may advantageously provide a reduced area for the semiconductor package 400 by enabling separate thicknesses and lateral dimensions of the polymeric die pads 414a and 414b appropriate for the dimensions of the semiconductor die 422a and 422b.

The semiconductor package 400 includes electrical connections 424 between the first semiconductor die 422a and one or more of the leads 402a, and between the second semiconductor die 422b and another or more of the leads 402a. The electrical connections 424 may be implemented as any of the connections disclosed in reference to the electrical connections 124 of FIG. 1G. A packaging material 426 is formed on the semiconductor die 422a and 422b, and the leads 402a, surrounding the polymeric die pads 414a and 414b, and covering the electrical connections 424. The packaging material 426 is electrically non-conductive, and may have any of the compositions disclosed in reference to the packaging material 126 of FIG. 1H. In this example, the leads 402a may extend from the packaging material 426 in a “J-lead” configuration. Other package type for the semiconductor package 400 are within the scope of this example.

Various features of the examples disclosed herein may be combined in other manifestations of example semiconductor packages. For example, the semiconductor package 300 of FIG. 3A and FIG. 3B or the semiconductor package 400 of FIG. 4A and FIG. 4B may have polymeric die pads 314 or 414a and 414b, respectively, formed by a punch process, as described in reference to FIG. 1B through FIG. 1D. Conversely, the semiconductor package 300 of FIG. 3A and FIG. 3B or the semiconductor package 400 of FIG. 4A and FIG. 4B may have pre-cut polymeric die pads 314 or 414a and 414b, respectively, assembled by a pick-and-place operation, as described in reference to FIG. 2B. Either of the semiconductor packages 100 or 200 may have more than one semiconductor die on the polymeric die pad 114 or 214, respectively. Either of the semiconductor packages 100 or 200 may have more than one polymeric die pad, and separate semiconductor die on each polymeric die pad. Any of the semiconductor packages 100 through 400 may have semiconductor die attached to the polymeric die pads by die attach paste or die attach film.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the following claims and equivalents.

What is claimed is:

1. A semiconductor package, comprising:
a lead frame portion including leads, the leads being electrically conductive and extending to an exterior of the semiconductor package;
a polymeric die pad attached to a plurality of the leads; and
a semiconductor die attached to the polymeric die pad; wherein:
the polymeric die pad is electrically non-conductive; and
the polymeric die pad extends laterally past the semiconductor die on all sides.

2. The semiconductor package of claim 1, wherein the polymeric die pad is attached to the plurality of the leads through a die pad adhesive.

3. The semiconductor package of claim 2, wherein the die pad adhesive is coterminous with the polymeric die pad.

4. The semiconductor package of claim 1, wherein the semiconductor die is attached to the polymeric die pad through a die attach paste.

5. The semiconductor package of claim 4, wherein the die attach paste extends laterally past the semiconductor die.

6. The semiconductor package of claim 4, wherein the die attach paste includes electrically conductive particles.

7. The semiconductor package of claim 1, wherein the semiconductor die is attached to the polymeric die pad through a die attach film.

8. The semiconductor package of claim 7, wherein the die attach film is coterminous with semiconductor die.

9. The semiconductor package of claim 1, wherein the polymeric die pad includes polyimide.

10. The semiconductor package of claim 1, wherein the semiconductor die is a first semiconductor die, and further including a second semiconductor die attached to the polymeric die pad.

11. The semiconductor package of claim 1, wherein:
the polymeric die pad is a first polymeric die pad;
the plurality of the leads is a first plurality of the leads; and
the semiconductor die is a first semiconductor die; and further including:
a second polymeric die pad attached to a second plurality of the leads; and
a second semiconductor die attached to the second polymeric die pad;
wherein:
the second polymeric die pad is electrically non-conductive; and
the second polymeric die pad extends laterally past the second semiconductor die on all sides.

12. A method of forming a semiconductor package, comprising:
attaching a polymeric die pad to leads of a lead frame, the polymeric die pad being electrically non-conductive; and
attaching a semiconductor die to the polymeric die pad, wherein the polymeric die pad extends laterally past the semiconductor die on all sides.

13. The method of claim 12, wherein a die pad adhesive is on the polymeric die pad, and wherein the polymeric die pad and the die pad adhesive are coterminous.

14. The method of claim 13, wherein attaching the polymeric die pad to the leads includes curing the die pad adhesive on the leads.

15. The method of claim 12, wherein attaching the semiconductor die to the polymeric die pad includes dispensing a die attach paste on the polymeric die pad and disposing the semiconductor die on the die attach paste.

16. The method of claim 15, wherein attaching the semiconductor die to the polymeric die pad includes curing the die attach paste, the die attach paste extending laterally past the semiconductor die.

17. The method of claim 15, wherein the die attach paste includes electrically conductive particles.

18. The method of claim 12, wherein a die attach film is on the semiconductor die, and wherein attaching the semiconductor die to the polymeric die pad includes curing the die attach film.

19. The method of claim 18, wherein the semiconductor die is pressed onto the polymeric die pad, through the die attach film, while curing the die attach film.

20. The method of claim 12, wherein the polymeric die pad includes polyimide.
